(19) United States
(12) Patent Application Publication
(10) Pub. No.: US 2017/0148759 A1
(43) Pub. Date: May 25, 2017

(54) BONDING APPARATUS AND BONDING METHOD

(71) Applicant: Shinkawa Ltd., Tokyo (JP)

(72) Inventors: Shigeru HAYATA, Tokyo (JP); Rei ANDO, Tokyo (JP); Yasushi SATO, Tokyo (JP)

(73) Assignee: Shinkawa Ltd., Tokyo (JP)

(21) Appl. No.: 15/342,381

(22) Filed: Nov. 3, 2016

Related U.S. Application Data
(63) Continuation of application No. PCT/JP2015/062813, filed on Apr. 28, 2015.

(30) Foreign Application Priority Data
May 7, 2014 (JP) 2014-096338

(51) Int. Cl. H01L 23/00

(52) U.S. Cl. CPC H01L 24/75; H01L 24/81; H01L 24/83; H01L 2224/75702; H01L 2224/75753; H01L 2224/75901; H01L 2224/8113; H01L 2224/81132; H01L 2224/8313; H01L 2224/83132

(57) ABSTRACT

A bonding apparatus 10 includes: a bonding head 18 configured to move a top camera 24 facing toward a bonding surface and a collet 22 disposed with an offset from the top camera 24, while integrally holding the top camera 24 and the collet 22; a bottom camera 28 facing toward the collet 22 so as to detect a position of a semiconductor chip 100 held by the collet 22 with respect to the collet 22; a reference mark 32 disposed within a view field of the bottom camera 28; and a control unit 40. The control unit 40 moves the bonding head 18 based on a position of the mark 32 recognized by the top camera 24, and then calculates a value of the offset based on a position of the collet 22 with respect to the mark 32 recognized by the bottom camera 28. With this, it is possible to provide a bonding apparatus capable of easily detecting an offset between a bonding tool and a position detection camera without providing a dedicated camera.

### TECHNICAL FIELD

The present invention relates to a bonding apparatus and a bonding method for bonding a chip onto a substrate.

### BACKGROUND ART

Conventionally, a die bonding apparatus, a flip chip bonding apparatus, and the like have been known as examples of a bonding apparatus for bonding a chip such as a semiconductor device on a substrate. Such a bonding apparatus holds and moves a chip using a bonding tool such as a collet, and performs bonding onto a substrate. Here, in order to perform bonding with a high accuracy, it is necessary to determine, prior to bonding, a position of a chip that is picked up by a bonding tool with respect to a bonding tool, and a condition of the chip (whether or not there are cracks and contamination). Therefore, conventionally, a die bonding apparatus or the like is provided with a bottom camera taking an image of a bonding tool that has picked up a chip is provided at a position immediately under a transfer path of the bonding tool, and determines a position of the chip with respect to the bonding tool and a configuration of the chip based on an image taken by the bottom camera.

Further, in order to perform bonding with a high accuracy, it is necessary to accurately detect a position on a substrate for attaching a chip. Therefore, conventionally, it is proposed that a position detection camera facing toward a working plane is provided near the bonding tool, the position detection camera takes an image of a chip attachment portion on a substrate, and a position of the chip attachment portion is detected based on the obtained image. In some quarters, it is proposed that the position detection camera and the bonding tool are provided for the bonding head separately from each other with a prescribed offset amount. In such a bonding apparatus, the offset amount between the bonding tool and the position detection camera changes due to a change over time attributable to a temperature change and abrasion. Such a change in the offset amount results in an error of the bonding position.

Thus, documents such as PTLs 1 to 6 disclose techniques for detecting an offset amount. For example, PTL 1 discloses a technique in which a bonding apparatus includes position detection camera for detecting a position of a component to be bonded and a tool for carrying out bonding that are disposed with an offset, wherein the position detection camera is moved above a reference member to measure a positional relation between the reference member and the position detection camera, the tool is moved above the reference member according to a previously recorded offset amount to measure a positional relation between the reference member and the tool using a bottom camera, and an accurate offset amount is obtained based on the measurement results.

Further, PTL 2 discloses a technique in which a charge coupling device within a camera is used as a reference member. Moreover, PTLs 3 and 4 disclose techniques in which a dedicated camera is provided separately from a position detection camera and a bottom camera in order to correct displacement of an inter-camera distance and an offset amount. Furthermore, PTLs 5 and 6 disclose techniques for correcting displacement of an inter-camera distance and an offset amount based on an image obtained by a position detection camera and a bottom camera.

### CITATION LIST

### Patent Literature

PTL 1: Japanese Patent No. 2982000

PTL 2: Japanese Patent No. 4105926

PTL 3: Japanese Patent No. 4128540

PTL 4: Japanese Patent No. 5344145

PTL 5: Japanese Patent No. 2780000

PTL 6: Japanese Unexamined Patent Application Publication No. 2006-210785

### SUMMARY OF INVENTION

### Technical Problems

However, the techniques according to PTLs 1 and 2 are basically intended for applications to a wire bonding apparatus, and not intended for applications in a bonding apparatus for bonding a chip of a semiconductor device or the like onto a substrate, such as a die bonding apparatus and a flip chip bonding apparatus. Further, both of the techniques according to PTLs 1 and 2 assume provision of a dedicated camera for offset detection.

The techniques according to PTLs 3 and 4 are basically intended for applications to a bonding apparatus for bonding a chip onto a substrate. However, the techniques according to PTLs 3 and 4 require an additional dedicated camera for measuring an offset amount or the like, separately from a position detection camera for measuring a chip attachment position and a bottom camera for measuring a chip held by a bonding tool. The configuration of the techniques according to PTLs 5 and 6 does not require a dedicated camera, but a complicated and time-consuming process has to be carried out in order to measure an offset amount or the like.

Thus, an object of the present invention is to provide a bonding apparatus for bonding a chip onto a substrate, which bonding apparatus is capable of easily detecting an offset between a bonding tool and a position detection camera without providing a dedicated camera for detecting the offset, and such a bonding method.

### Solution to Problems

A bonding apparatus according to the present invention is a bonding apparatus for bonding a chip onto a substrate, the apparatus including: a bonding head configured to move a first camera facing toward a bonding surface and a bonding tool disposed with an offset from the first camera, while integrally holding the first camera and the bonding tool; a second camera facing toward the bonding tool so as to detect a position of the chip held by the bonding tool with respect to the bonding tool; a reference mark disposed within a view field of the second camera; and a control unit configured to control movement of the bonding head, wherein the control unit moves the bonding head based on a position of the reference mark recognized by the first camera, and then calculates a value of the offset based on a position of the bonding tool with respect to the reference mark recognized by the second camera.

In a different preferred aspect, bonding is performed by feeding back the value of the offset calculated by the control unit to a subsequent bonding process. In a different preferred aspect, one of the first camera and the second camera takes an image of an imaging target without stopping the bonding head by causing electronic flash corresponding to the camera to emit light at imaging timing at which the imaging target passes through a view field of the camera as the bonding head moves, and the control unit calculates the value of the offset based on the taken image obtained without stopping the bonding head.

In a different preferred aspect, the control unit detects the position of the chip with respect to the bonding tool based on an image taken by the second camera for detecting the position of the bonding tool with respect to the reference mark.

In a different preferred aspect, the second camera is an infrared camera for taking an image by infrared light. Further, in a different preferred aspect, the reference mark is disposed on an end of a depth of field of the second camera. In a different preferred aspect, the second camera includes a mechanism for partially changing a focal position within the view field.

A bonding method according another aspect of the present invention is a bonding method for bonding a chip onto a substrate employing a bonding apparatus including: a bonding head configured to move a first camera facing toward a bonding surface and a bonding tool disposed with an offset from the first camera, while integrally holding the first camera and the bonding tool; and a second camera facing toward the bonding tool so as to detect a position of the chip held by the bonding tool with respect to the bonding tool, the method including the steps of: recognizing a position of a reference mark using the first camera, the reference mark being disposed within a view field of the second camera; recognizing a position of the bonding tool with respect to the reference mark using the second camera after the bonding head is moved based on the position of the recognized reference mark; and calculating a value of the offset based on the position of the bonding tool with respect to the recognized reference mark.

### Advantageous Effect of Invention

According to the present invention, it is possible to easily detect an offset using a first camera facing toward a bonding surface and a second camera facing toward a bonding tool that are also provided for the conventional bonding apparatus.

### BRIEF DESCRIPTION OF DRAWINGS

FIG. 1 is a diagram illustrating a configuration of a bonding apparatus according to an embodiment of the present invention.

FIG. 2 is a diagram illustrating a configuration of a portion around a bottom camera.

FIG. 3a is an isometric view of a first example of a reference member.

FIG. 3b is a schematic view of an image obtained when an image of the reference member of FIG. 3a is taken by a camera.

FIG. 3c is an isometric view of a second example of a reference member.

FIG. 3d is a schematic view of an image obtained when an image of the reference member of FIG. 3c is taken by a camera.

FIG. 4a is a first illustrative diagram of a first principle of offset measurement.

FIG. 4b is a second illustrative diagram of a first principle of offset measurement.

FIG. 5a is a first illustrative diagram of a second principle of offset measurement.

FIG. 5b is a second illustrative diagram of a second principle of offset measurement.

FIG. 6a is a first illustrative diagram of a third principle of offset measurement.

FIG. 6b is a second illustrative diagram of a third principle of offset measurement.

FIG. 6c is a third illustrative diagram of a third principle of offset measurement.

FIG. 7a is a first illustrative diagram of a fourth principle of offset measurement.

FIG. 7b is a second illustrative diagram of a fourth principle of offset measurement.

FIG. 8 is a flowchart showing a flow of a bonding process.

FIG. 9 is a flowchart showing a flow of a different bonding process.

FIG. 10 is a diagram illustrating a configuration of a different bonding apparatus.

FIG. 11 is a diagram illustrating a configuration of a portion around a different bottom camera.

FIG. 12 is a diagram illustrating a configuration of a different bottom camera.

FIG. 13 is a diagram illustrating a configuration of a portion around a different bottom camera.

FIG. 14 is a perspective view of an optical element used for the different bottom camera.

### DESCRIPTION OF EMBODIMENT

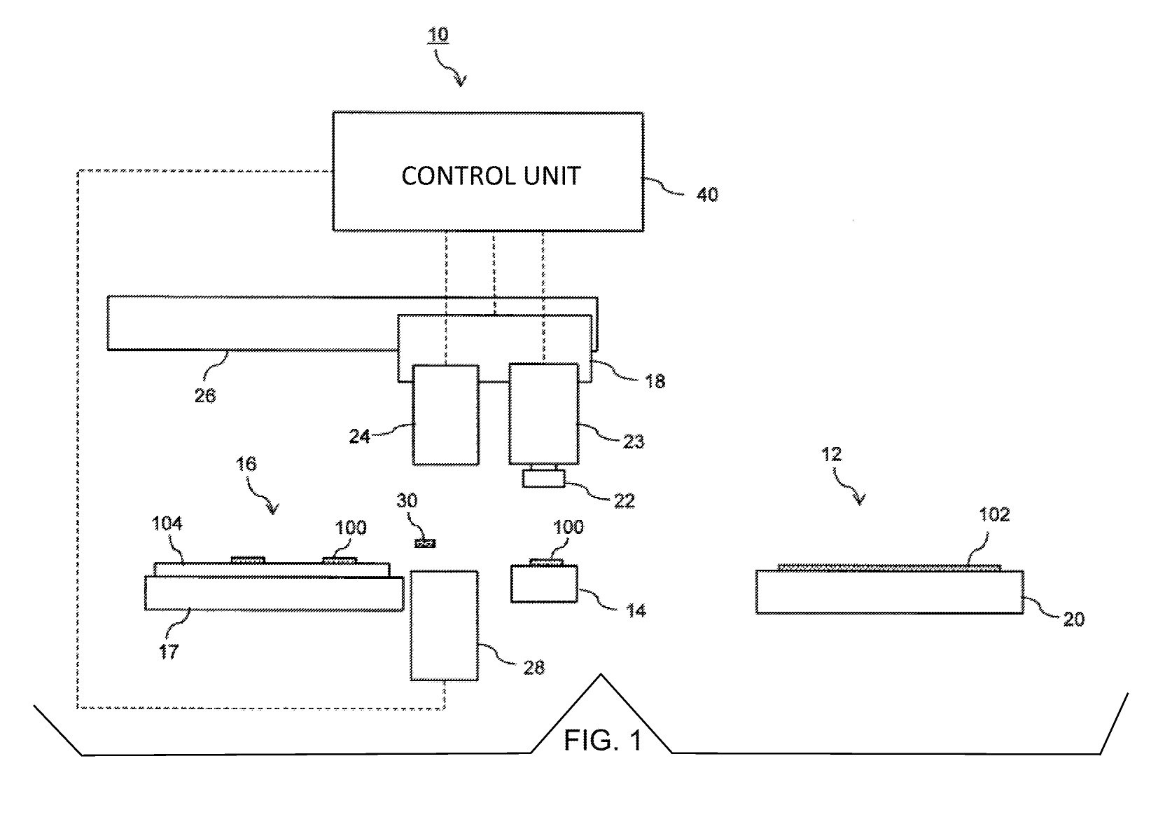

Hereinafter, a bonding apparatus 10 according to an embodiment of the present invention will be described with reference to the drawings. FIG. 1 is a diagram illustrating a configuration of the bonding apparatus 10 according to the embodiment of the present invention. The bonding apparatus 10 is a die bonding apparatus that performs positioning of a semiconductor chip 100 (die) as an electronic component to an attachment portion on a substrate 104, and performs bonding.

The bonding apparatus 10 includes: a chip feeding unit 12, an intermediate stage 14 on which a chip is placed, a bonding stage unit 16 for supporting the substrate 104, a bonding head 18, a collet 22 and a top camera 24 as a first camera that are attached to the bonding head 18 via a Z-axis drive mechanism 23, a bottom camera 28 as a second camera, a reference member 30 disposed near the bottom camera 28, an XY table 26 for moving the bonding head 18, and a control unit 40 for controlling driving of the bonding apparatus 10 as a whole.

On a stage 20 of the chip feeding unit 12, there is placed a wafer 102 that is diced into semiconductor chips 100 in a grid pattern applied to a film on their back surfaces. The semiconductor chips 100 are transferred to and placed on the intermediate stage 14 by a transfer head that is not illustrated.

The bonding stage unit 16 is a stage for bonding the semiconductor chip 100 to an attachment portion of the substrate 104. The bonding stage unit 16 is provided with a movement mechanism 17 for moving the substrate 104 in a horizontal direction, a heater (not illustrated) for heating the substrate 104, and the like. Driving of all of these components is controlled by the control unit 40.

To the bonding head 18, the collet 22 and the top camera 24 are attached separately from each other by a prescribed offset distance. The collet 22 is a bonding tool for suction-holding the semiconductor chip 100 placed on the intermediate stage 14, transferring the semiconductor chip 100 to the bonding stage unit 16, and bonding the semiconductor chip 100 to the substrate 104 disposed on the bonding stage unit 16. The collet 22 is in a cuboid shape or circular truncated cone shape. Its central axis is disposed in a vertical direction perpendicular to a working plane on which the intermediate stage 14 or the bonding stage unit 16 is provided. By movement of the bonding head 18, the collet 22 is configured so as to be able to move from a position immediately above the intermediate stage 14 to a position immediately above the bonding stage unit 16. Further, the collet 22 is attached to the bonding head 18 via the Z-axis drive mechanism 23 for up-down movement and a θ-axis drive mechanism (not illustrated) for rotary movement, and is able to make linear movement along a Z axis and rotational movement about the Z axis with respect to the bonding head 18.

The top camera 24 is a camera for measuring a position of the attachment portion of the substrate 104 supported by the bonding stage unit 16. The top camera 24 has an optical axis in a vertically downward direction, and is able to take an image on a side of the working plane on which the substrate 104 or the like is placed. The top camera 24 is also used for measuring an offset distance as will be later described. The bonding head 18 to which the collet 22 and the top camera 24 are attached is attached to the XY table 26, and is able to move in an XY direction.

The bottom camera 28 is disposed immediately below a transfer path of the collet 22, that is, fixedly provided between the intermediate stage 14 and the bonding stage unit 16. The bottom camera 28 has a vertically upward optical axis. In other words, the bottom camera 28 is disposed facing toward the collet 22 and the top camera 24, and is able to take an image of a tip end surface (bottom surface) of the collet 22.

Near the bottom camera 28, the reference member 30 is fixedly provided. As will be later described, the reference member 30 is a member providing a reference when an offset distance between the collet 22 and the top camera 24 is measured, and is provided with a reference mark 32 of an identical shape at an identical position on two sides. The reference member 30 is disposed at a position at which the reference member 30 may not hinder imaging of the collet 22 by the bottom camera 28, and the reference mark 32 is positioned within a view field of the bottom camera 28.

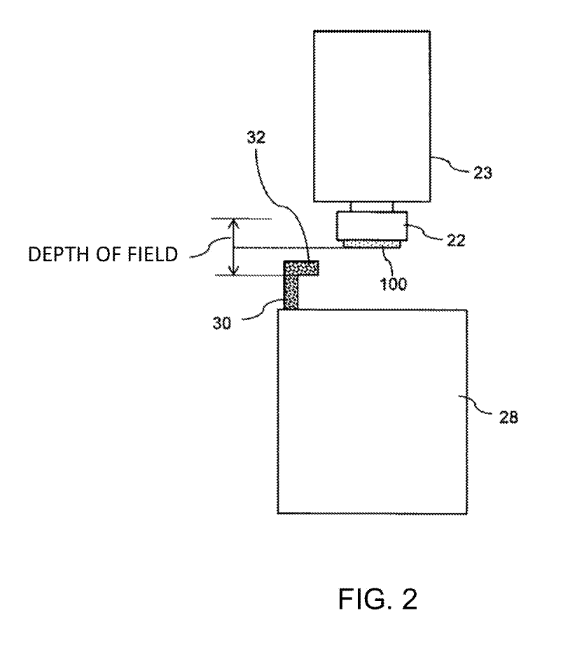

More specifically, as illustrated in FIG. 2, the reference member 30 is provided such that the reference mark 32 is positioned on a lower end of a depth of field of the bottom camera 28 (an end on a side of the bottom camera 28). The reference member 30 is provided at such a position in order to avoid interference with the collet 22. Specifically, in this embodiment, an image of the collet 22 is taken by the bottom camera 28 for measurement of a position and an offset distance of the semiconductor chip 100 with respect to the collet 22. At this time, the collet 22 moves down near a height of the depth of field of the bottom camera 28. In this embodiment, in order to allow the bottom camera 28 to recognize the reference mark 32 while avoiding interference with the collet 22, the reference mark 32 is positioned on a lower end of the depth of field of the bottom camera 28. Here, in general, as the bottom camera 28 has a low magnification and a wide field depth, the interference between the collet 22 and the reference member 30 within the depth may be avoided. Further, even when the reference mark 32 is provided at a position more or less away from the depth of field, it is possible to prevent deterioration of accuracy in measurement of an offset distance by registration of an image of the reference mark 32 as a reference in a blurry image that is out of focus.

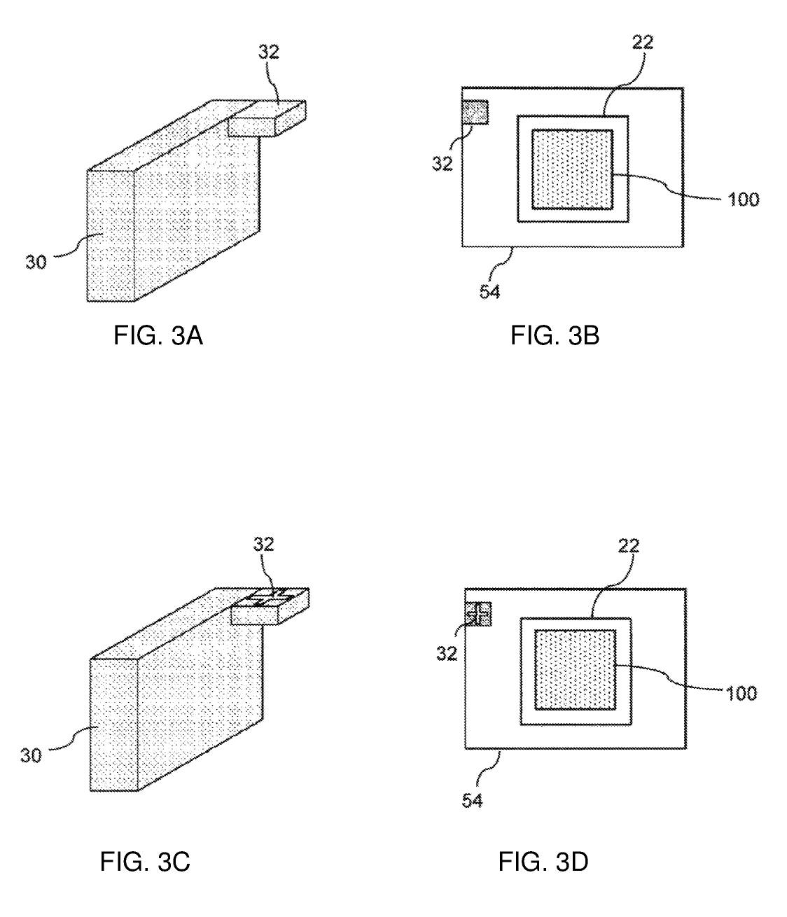

The shape of the reference mark 32 is not particularly limited as long as its position and posture within the camera view field may be recognized by the camera. Therefore, the reference mark 32 may be a rectangular mark configured as a rectangular block as illustrated in FIGS. 3a, 3b, or a cross-shaped mark configured as a cross-shaped through hole defined in the rectangular block as illustrated in FIGS. 3c, 3d. Alternatively, the reference mark 32 may be a mark configured such that a cross-shaped pattern is provided by coating glass by chromium or the like. Further, the reference mark 32 may be a mark configured such that a cross-shaped pattern is provided by coating a lens of the bottom camera itself by chromium or the like. It should be noted that in FIGS. 3a-3d, a reference number 54 is a schematic view of an image obtained when an image of the collet 22 is taken by the bottom camera 28 (hereinafter referred to as the “second image 54”).

Moreover, for a favorable bonding process, it is necessary that the reference member 30 may not disturb recognition of the collet 22 by the bottom camera 28, and that the reference mark 32 is positioned within the view field of the bottom camera 28. Accordingly, it is desirable that the reference mark 32 be positioned near an end of the view field of the bottom camera 28 as illustrated in FIGS. 3a-3d.

With the bonding apparatus 10 of such a type, the semiconductor chip 100 placed on the intermediate stage 14 is suctioned and held by the collet 22, and bonded to an attachment portion on the substrate 104. At this time, in order to ensure positional accuracy for attachment, prior to bonding, a position of the semiconductor chip 100 suctioned and held by the collet 22 corresponding to the collet 22 is recognized by the bottom camera 28, and a position of the attachment portion on the substrate 104 is recognized by the top camera 24. Then, after moving and positioning the collet 22 and the substrate 104 based on the positions respectively recognized by the corresponding cameras 24 and 28, the semiconductor chip 100 is bonded to the attachment portion on the substrate 104.

It should be noted that conventionally, such positioning of the collet 22 and the substrate 104 is performed on an assumption that an offset distance between the collet 22 and the top camera 24 is always constant. However, in practice, the offset distance changes delicately depending on a temperature change or a change over time. In addition, if the offset distance changes from a previously defined reference offset distance D, an error by an amount of the change is produced, resulting in deterioration of the positional accuracy in bonding.

Thus, in some quarters, it is proposed to measure the offset distance by providing a camera dedicated for offset measurement, or complicated steps. However, such a conventional technique poses problems of an increase in cost accompanied by addition of the dedicated camera, and increased processing time accompanied by addition of the complicated and time-consuming steps.

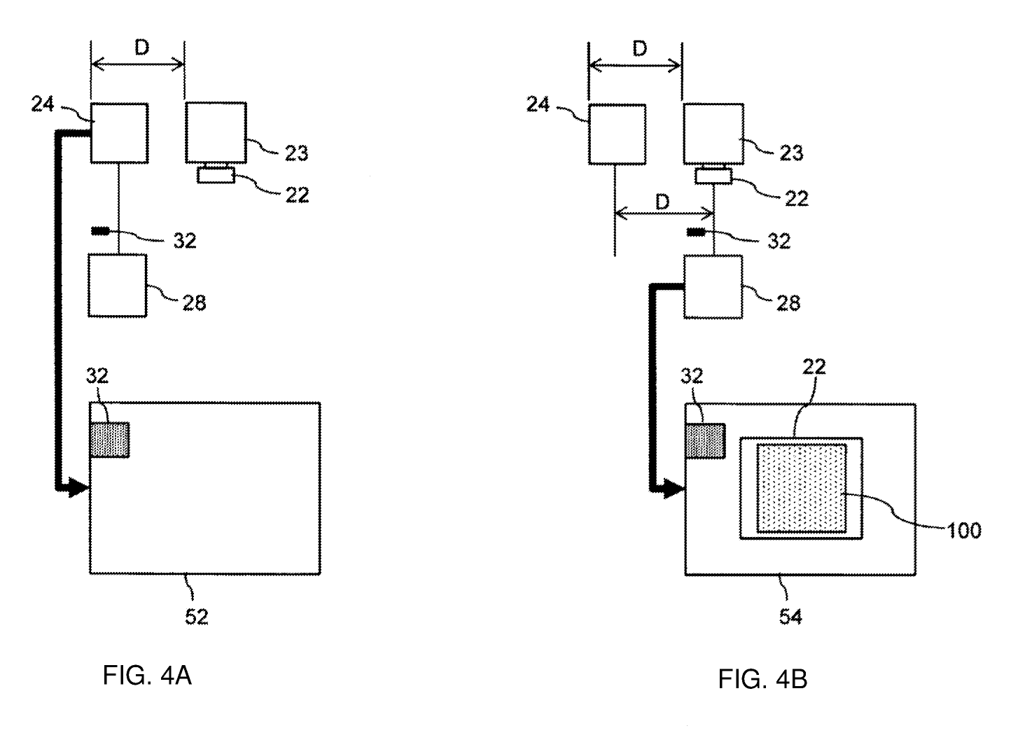

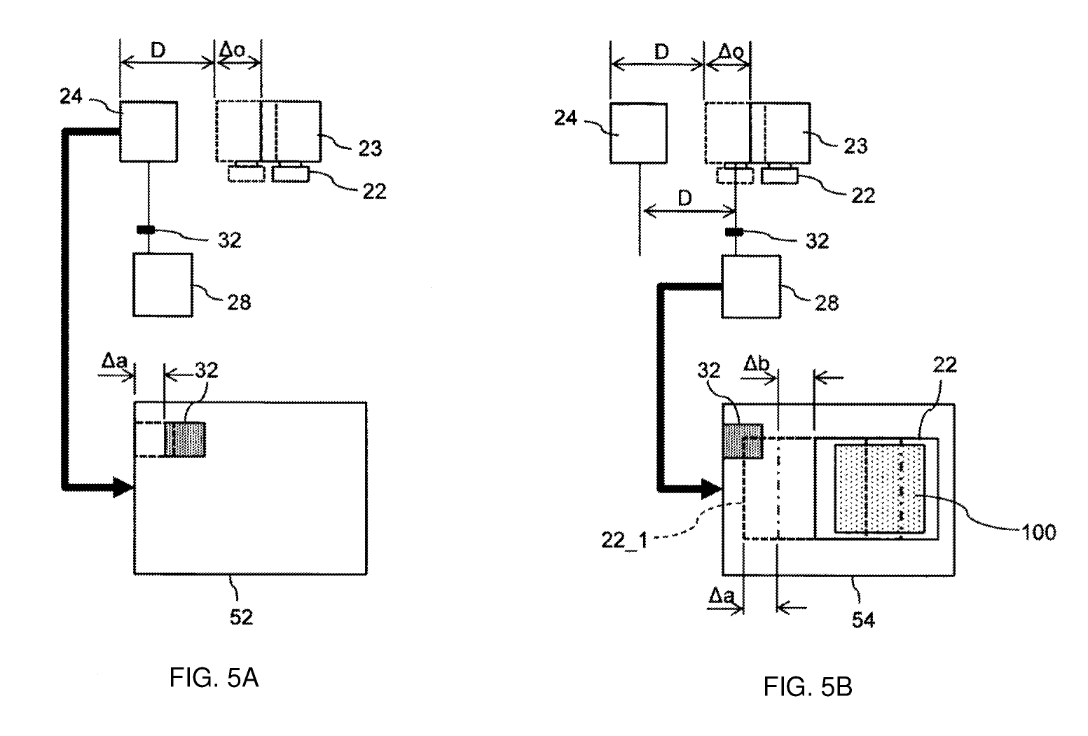

Therefore, in this embodiment, the offset distance is measured based on images obtained by the top camera 24 and the bottom camera 28 that are also provided for the conventional bonding apparatus 10. Further, it is intended to prevent the processing time from increasing by performing such measurement of the offset distance in parallel with a bonding step. Before explaining the flow of the measurement of the offset distance, principles of the measurement of the offset distance in this embodiment will be described with reference to FIGS. 4a, 4b, FIGS. 5a, 5b and the like.

First, in order to measure the offset distance, the control unit 40 previously records the reference offset distance D, a first reference position, and a second reference position. The reference offset distance D is a design or current offset distance between the collet 22 and the top camera 24. The offset distance should essentially be the reference distance D, but in practice, a slight error Δo is produced due to a temperature change or a change over time.

The first reference position is, as illustrated in FIG. 4a, a position of the reference mark 32 within an image obtained by the top camera 24 in a state in which the top camera 24 is positioned immediately above the bottom camera 28, that is, a state in which an optical axis of the top camera 24 and an optical axis of the bottom camera 28 coincide. Hereinafter, an image obtained when the top camera 24 takes an image on a side of the bottom camera 28 is referred to as a first image 52. The first image 52 may be taken based on a method of reflective illumination (such as coaxial illumination) using illumination of the top camera 24, or based on a backlight method using coaxial illumination of the bottom camera 28.

The second reference position is, as illustrated in FIG. 4b, a position of the collet 22 with respect to the reference mark 32 within the second image 54 obtained by the bottom camera 28 in a state in which the collet 22 is positioned immediately above the bottom camera 28, that is, a state in which a central axis of the collet 22 and the optical axis of the bottom camera 28 coincide. The second image 54 may be taken based on a method of reflective illumination (such as coaxial illumination) using illumination of the bottom camera 28.

Next, as illustrated in FIGS. 5a, 5b, a case in which an offset distance between the collet 22 and the top camera 24 is D+Δo is assumed. In this case, as illustrated in FIG. 5a, the top camera 24 is moved immediately above the bottom camera 28 to obtain the first image 52. At this time, if there is displacement of an amount Δa between the optical axis of the top camera 24 and the optical axis of the bottom camera 28, the reference mark 32 within the first image 52 is displaced from the first reference position by Δa. The displacement amount Δa of the reference mark 32 within the first image 52 may be obtained by analyzing the first image 52.

Next, as illustrated in FIG. 5b, it is assumed that the top camera 24 and the collet 22 are moved by the reference offset distance D from the above state. At this time, if the offset distance between the top camera 24 and the collet 22 is the reference offset distance D (that is, if the error Δo is not present), the position of the collet 22 with respect to the reference mark 32 within the second image 54 is also displaced by Δa with respect to the second reference position, and the collet 22 should be seen as represented by a rectangular 22_1 in a broken line within the second image 54. However, if there is the error amount Δo in the offset distance, the position of the collet 22 with respect to the reference mark 32 within the second image 54 is displaced by Δb=Δo−Δa with respect to the second reference position. The displacement amount Δb of the collet 22 may be obtained by analyzing the second image 54. Then, by adding Δa and Δb obtained respectively from the first image 52 and the second image 54, the error amount Δo in the offset distance may be obtained (Δo=Δa+Δb).

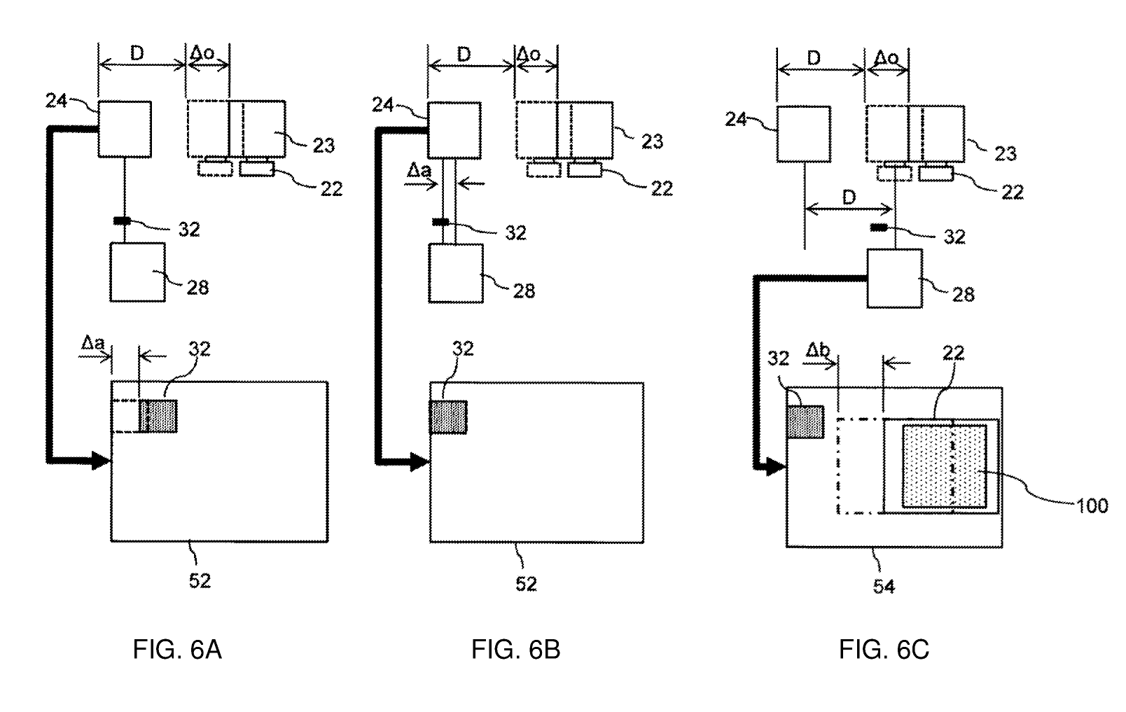

In the examples shown in FIGS. 5a, 5b, as the bonding head 18 is moved by the reference offset distance D without eliminating the displacement amount Δa of the reference mark 32 within the first image 52, the error amount Δo of the offset distance is Δo=Δa+Δb. However, as illustrated in FIG. 6b, the bonding head 18 may be moved by the reference offset distance D after the bonding head 18 is moved prior to the movement by the reference offset distance D so that the displacement amount Δa of the reference mark 32 within the first image 52 becomes zero, that is, the reference mark 32 within the first image 52 is positioned at the first reference position. In this case, the positional displacement amount Δb of the collet 22 with respect to the reference mark 32 within the second image 54 is directly taken as the error amount Δo.

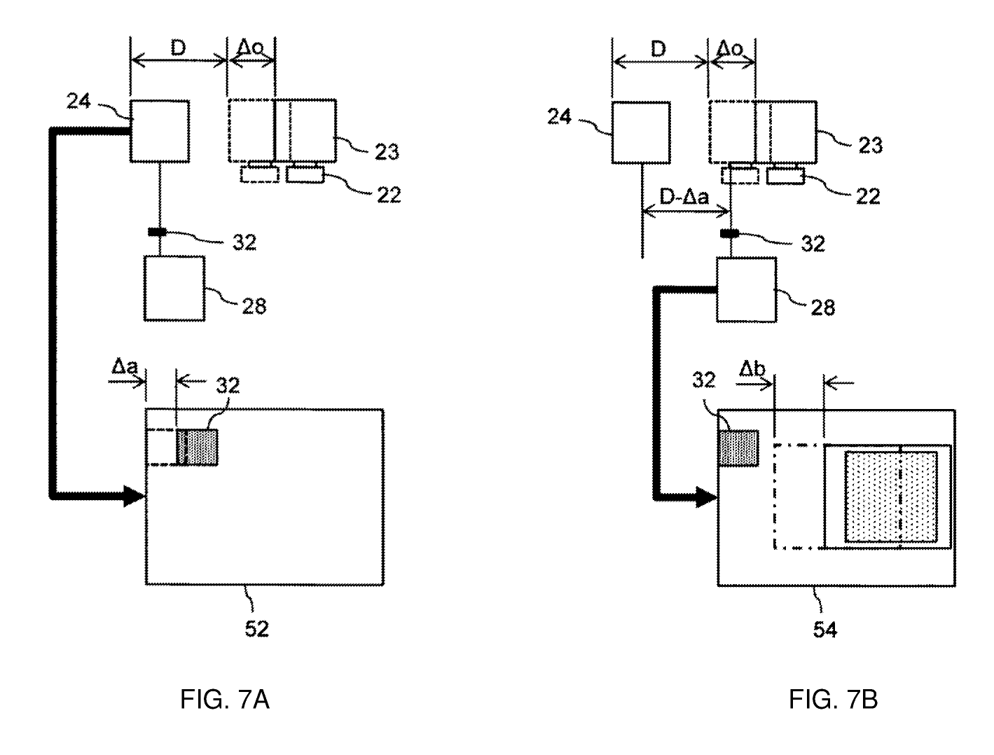

Further, as illustrated in FIGS. 7a, 7b, an amount of movement of the bonding head 18 after the first image 52 is obtained may be a distance considering the displacement amount Δa of the reference mark 32 within the first image 52, that is, D−Δ, instead of the reference offset distance D. Also in this case, after the movement by the distance D−Δa, the positional displacement amount Δb of the collet 22 with respect to the reference mark 32 within the obtained second image 54 is directly taken as the error amount Δo.

Here, as can be seen clearly from the previous description, according to this embodiment, in the measurement of the offset distance, the bottom camera 28 always takes an image of the collet 22 to obtain the second image 54. In this embodiment, the second image 54 is obtained after the semiconductor chip 100 is picked up by the collet 22, and before the semiconductor chip 100 is bonded to the substrate 104, that is, while the collet 22 is suctioning and holding the semiconductor chip 100. Then, a position of the semiconductor chip 100 with respect to the collet 22, is measured, in addition to the offset distance, based on the obtained second image 54. In other words, in this embodiment, the measurement of the offset distance and the measurement of the position of the semiconductor chip 100 are performed at the same time in a single imaging process. With this, it is possible to reduce a number of special steps added for the measurement of the offset distance, and to prevent the processing time from increasing.

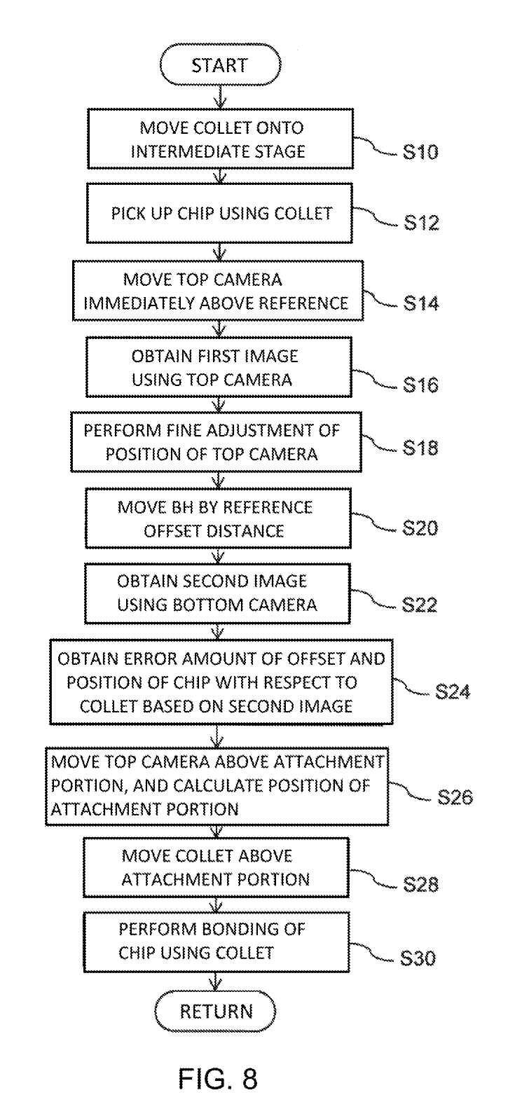

Next, a flow of bonding by the bonding apparatus 10 will be described with reference to FIG. 8. FIG. 8 is a flowchart showing a flow of bonding by the bonding apparatus 10 according to this embodiment. FIG. 8 shows a flow of a bonding process when the offset distance is obtained using the principle described with reference to FIGS. 6a, 6b, 6c.

When the semiconductor chip 100 is bonded onto the substrate 104, first, the control unit 40 moves the bonding head 18 to position the collet 22 immediately above the intermediate stage 14 (S10). The collet 22 is moved downward in this state, and the semiconductor chip 100 is suctioned and held, and picked up with a tip of the collet 22 (S12). If the semiconductor chip 100 is successfully suctioned and held, the collet 22 is moved upward to a prescribed height in order to prevent interference.

Next, the control unit 40 moves the bonding head 18 to position the top camera 24 immediately above the bottom camera 28, that is, above the reference member 30 (S14). Then, in this state, the top camera 24 takes an image on the side of the bottom camera 28, and obtains the first image 52 (S16). The control unit 40 calculates the displacement amount Δa of the reference mark 32 within the first image 52 based on the first image 52. Then, based on Δa thus obtained, the bonding head 18 is moved so that the reference mark 32 within the first image 52 is positioned at the first reference position, that is, the state illustrated in FIG. 7b is realized (S18).

Once the displacement amount Δa of the reference mark 32 within the first image 52 becomes zero, the control unit 40 then moves the bonding head 18 by the prescribed reference offset distance D (S20). With this movement, the collet 22 is positioned substantially immediately above the bottom camera 28. Once this state is realized, the bottom camera 28 takes an image of the collet 22 to obtain the second image 54 (S22). Here, when taking an image, the collet 22 is moved down to a substantially central height in the depth of field of the bottom camera 28. The control unit 40 calculates the error amount Δo of the offset distance and the positional displacement amount of the semiconductor chip 100 with respect to the collet 22 based on the second image 54 (S24). In this case, the error amount Δo of the offset distance is the positional displacement amount Δb of the collet 22 with respect to the reference mark 32 within the obtained second image 54 as described above with reference to FIGS. 7a, 7b (Δo=Δb). Further, similarly to the conventional technique, the control unit 40 performs calculation of the positional displacement amount of the semiconductor chip 100 with respect to the collet 22, pass/fail determination on of the semiconductor chip 10, and the like based on the obtained second image 54. As a result of the image analysis, if it is determined that the semiconductor chip 100 has a defect such as cracks, the bonding process of the semiconductor chip 100 is stopped. If the semiconductor chip 100 has no defect, the control unit 40 records the error amount Δo of the offset distance, the positional displacement amount of the semiconductor chip 100, and the like that are obtained here.

Subsequently, the control unit 40 moves the top camera 24 above the attachment portion on the substrate 104 (S26). Then, an accurate position of the attachment portion is calculated based on the image obtained by the top camera 24. Thereafter, the control unit 40 moves the bonding head 18 to move the collet 22 to a position immediately above the attachment portion (S28). In controlling the movement, correction is performed so that the collet 22 comes to the position immediately above the attachment portion, considering the error amount Δo of the offset distance and the positional displacement amount of the semiconductor chip 100 that are obtained in Step S24. Then, finally, the collet 22 is moved down near the substrate 104 to bond the semiconductor chip 100 onto the attachment portion on the substrate 104 (S30). Upon completion of bonding of a single semiconductor chip 100, the process returns to Step S10 to perform bonding of a next semiconductor chip 100. It should be noted that in the next bonding process, D+Δo obtained by adding the error amount Δo to a true offset distance obtained by the measurement, that is, the prescribed offset distance D, is fed back as a new offset distance (D=D+Δo).

As can be seen clearly from the previous description, in this embodiment, the error amount Δo of the offset distance is calculated based on images taken by the top camera 24 and the bottom camera 28 that are conventionally provided for the bonding apparatus 10. Therefore, it is not necessary to additionally provide a dedicated camera for offset measurement, and thus to effectively prevent an increase in cost of the bonding apparatus 10. Further, in this embodiment, the imaging step for taking an image of the collet 22 by the bottom camera 28, essential to the calculation of the positional displacement of the semiconductor chip 100 with respect to the collet 22 and the like, is directly employed as the imaging step for taking an image of the collet 22 by the bottom camera 28, essential to the calculation of the error amount Δo of the offset distance. In other words, as the measurement of the error amount Δo of the offset distance is performed employing the step that is originally essential, it is possible to effectively prevent the processing time from increasing.

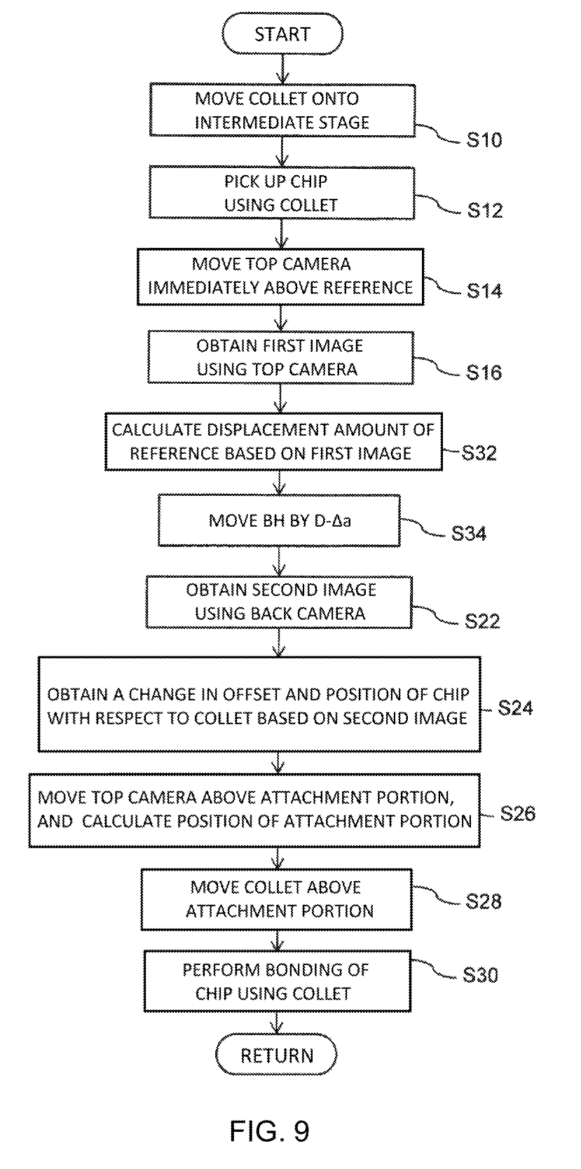

Next, a flow of a different bonding process will be described with reference to FIG. 9. FIG. 9 is a flowchart showing a flow of a bonding process when the offset distance is obtained using the principle described with reference to FIGS. 7a, 7b.

In this bonding process, after the first image 52 is obtained by the top camera 24 (S16), the bonding head is moved by D−Δa immediately after calculation of (S34) the displacement amount Δa of the reference mark 32 within the first image 52 (S32), without performing a fine adjustment step for positioning the top camera 24 at the first reference position (S18). Then, the positional displacement amount Δb of the collet 22 with respect to the reference mark 32 within the second image 54 obtained thereafter is calculated as the error amount Δo of the offset.

With such a configuration, it is possible to eliminate the step for fine adjustment of the position of the top camera (S18), and thus to further reduce the processing time. In particular, according to the configuration that does not require the step for fine adjustment of the position of the top camera 24, picking up of the semiconductor chip 100 by the collet 22 (S12) and obtaining of the first image 52 by the top camera 24 (S16) may be performed in parallel. Specifically, when the first image 52 is obtained, the bonding head 18 should naturally stand still. Having the bonding head 18 stand still just for obtaining the first image 52 in this manner results in increased processing time. On the other hand, when the semiconductor chip is picked up, the bonding head 18 should inevitably stand still. If the first image 52 by the top camera 24 is obtained during the pickup period in which the bonding head 18 inevitably stands still, the processing time may not be unnecessarily spent, and it is possible to effectively prevent the processing time from increasing. Thus, picking up of the semiconductor chip 100 and obtaining of the first image 52 may be performed in parallel, by setting the positions of the top camera 24 and the bottom camera 28 so that the bottom camera 28 is positioned immediately below the top camera 24 when the collet 22 is positioned immediately above the intermediate stage 14. In such a configuration, the bonding head 18 operates in the same manner as in the conventional bonding process, making processing time only for offset measurement unnecessary.

Here, in the above description, only the bonding apparatus 10 that employs an intermediate stage 14 method in which the semiconductor chip 100 fed from the chip feeding unit 12 is temporarily placed on the intermediate stage 14 is taken as an example. However, the technique of this embodiment may be applied to the bonding apparatus 10 that employs a direct pick-up method in which the semiconductor chip 100 picked up from the wafer 102 is directly bonded to the substrate 104. Further, in the above description, a die bonding apparatus is taken as an example. However, the technique of this embodiment may be applied to a bonding apparatus of different types, such as a flip chip bonding apparatus, as long as the apparatus handles chip-type components. The technique of this embodiment may also be applied to similar processes for mounting a component piece such as a MEMS device, a biological device, or a semiconductor package, in addition to the semiconductor chip.

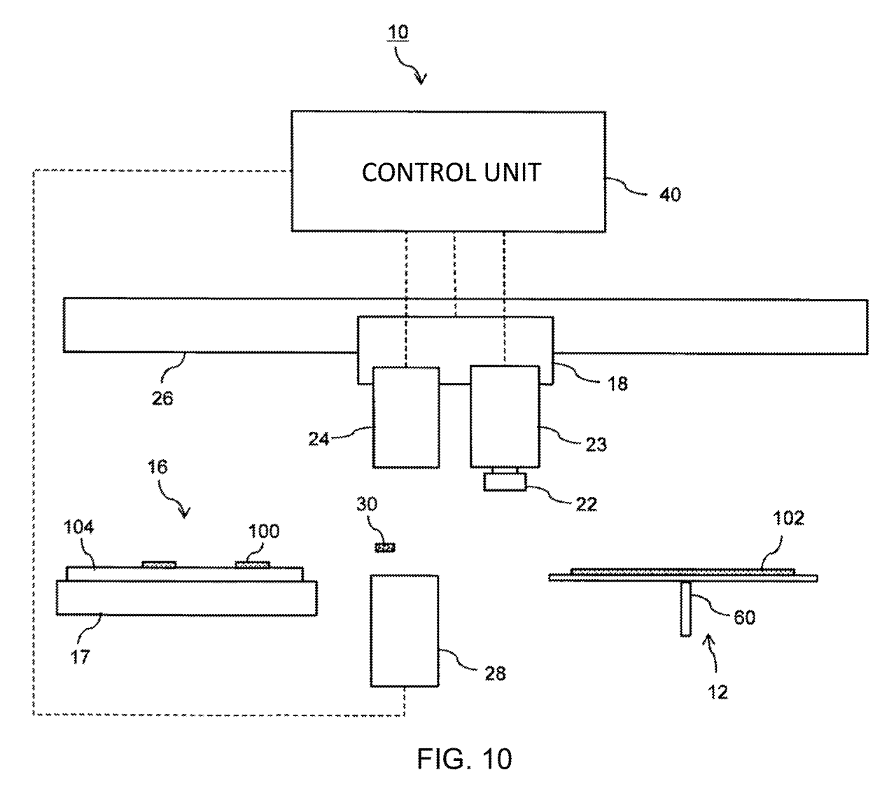

FIG. 10 is a schematic configurational diagram illustrating a die bonding apparatus 10 employing the direct pick-up method, to which the technique of this embodiment is applied. The die bonding apparatus 10 is different from the bonding apparatus 10 in FIG. 1 in that the intermediate stage 14 is eliminated. The wafer 102 is provided with a dicing tape or the like, and a plunge-up unit 60 is provided on a back surface of the dicing tape. The collet 22 suctions and holds the semiconductor chip 100 that is plunged up by the plunge-up unit 60, and transfers the semiconductor chip 100 onto the substrate 104. The bottom camera 28 and the reference member 30 may be provided in the middle of a path of the movement from the wafer 102 to the substrate 104.

Further, the above description takes the example in which the collet 22 and the top camera 24 are stopped immediately above the bottom camera 28 in order to obtain the first image and the second image. However, the first image and the second image may be obtained without stopping the collet 22 and the top camera 24 by causing illumination of the top camera 24 and the bottom camera 28 to emit light by electronic flash.

For example, the illumination in the top camera 24 is caused to emit light by electronic flash and the first image is obtained by the top camera 24 at timing at which the top camera 24 passes immediately above the bottom camera 28 (that is, imaging timing at which the reference member 30 as an imaging target passes through a view field of the top camera 24). Further, the illumination in the bottom camera 28 is caused to emit light by electronic flash and the second image is obtained by the bottom camera 28 at timing at which the collet 22 passes immediately above the bottom camera 28 (that is, imaging timing at which the collet 22 as an imaging target passes through the view field of the bottom camera 28). At this time, it is desirable that electronic-flash light-emitting time t1 be 1 μs or shorter, and LED illumination be used as the illumination of the cameras 24 and 28 in order to carry out such short-time light emission. Moreover, by making exposure time t2 of the cameras 24 and 28 to be longer than the electronic-flash light-emitting time t1, exposure is performed substantially only during time t1 in which light is emitted by electronic flash. In other words, it is possible to adjust timing for obtaining the first image and the second image only by adjusting timing of electronic-flash light emission.

Further, as a trigger for causing the illumination in the top camera 24 and the bottom camera 28 to emit light by electronic flash when the first image and the second image are obtained, the control unit 40 obtains the timing at which each of the collet 22 and the top camera 24 passes immediately above the bottom camera 28 by detecting the position of the collet 22 of the bonding head 18 from an encoder attached to an XY table. With this, it is possible to obtain and correct a change in the offset amount between the collet 22 and the top camera 24 without influencing takt time in a normal bonding sequence of the apparatus.

Here, when moving speed of the top camera 24 and the collet 22 is v and a ratio of the top camera 24 and the bottom camera 28 is β, a wavering amount Δa of the image in the charge coupling devices of the cameras 24 and 28 is Δa=β×v×t1. By adjusting the moving speed v and the electronic-flash light-emitting time t1 so that the wavering amount Δa is smaller than 1 pixel, it is possible to obtain images equivalent to those obtained when the collet 22 and the top camera 24 are stopped. Further, even when the wavering amount Δa is 1 pixel or more, it is easily possible to correct the wavering to obtain a true value by averaging the wavering amount Δa of the various parameters (β, v, t1) if values of the parameters are known. As a result, as the first image and the second image may be obtained without stopping the collet 22 and the top camera 24, it is possible to further reduce the processing time of the apparatus.

Further, the above description takes the example in which the offset measurement is performed in the bonding process of each of the semiconductor chips 100. However, the offset measurement is not required to perform every time, and may be performed only at specific timing. For example, the offset measurement may be performed only when prescribed time period has passed, when bonding of a prescribed number of chips is completed, when the bonding apparatus is started, or when the wafer 102 is replaced.

Moreover, the above description takes the example in which the semiconductor chip 100 is smaller than the collet 22. However, there is a case in which the semiconductor chip 100 is larger than the bottom surface of the collet 22, and the bottom surface of the collet 22 is entirely covered by the semiconductor chip 100. In such a case, it is not possible to detect the positional displacement amount of the semiconductor chip 100 with respect to the collet 22 or the positional displacement amount Δb of the collet 22 with respect to the reference mark 32. Therefore, in order to avoid such a problem, the bottom camera 28 may be configured as an infrared camera (in particular, a near-infrared camera), and the collet 22 may be recognized by an infrared light source. The near-infrared light is transmissive to silicon that is a material of the semiconductor chip 100. Therefore, the shape of the collet 22 covered by the semiconductor chip 100 may be recognized by using an infrared camera. In addition, by using an infrared camera, it is possible to detect cracks on a surface of the semiconductor chip 100, as well as cracks inside the chip.

Further, in this embodiment, in order to prevent interference between the collet 22 and the reference member 30, the reference mark 32 is provided at the end of the depth of field of the bottom camera 28. However, depending on the type of the camera, there is a case in which a sufficient depth of field may not be obtained, and a sufficient distance between the reference member 30 and the collet 22 may not be ensured. In order to avoid such a problem, the bottom camera 28 may have a double focus configuration with two working distances (focal positions). In order to provide a double focus configuration, for example, an optical element for varying the working distance (focal position) is partially disposed or removed between the charge coupling device of the bottom camera 28 and an imaging object.

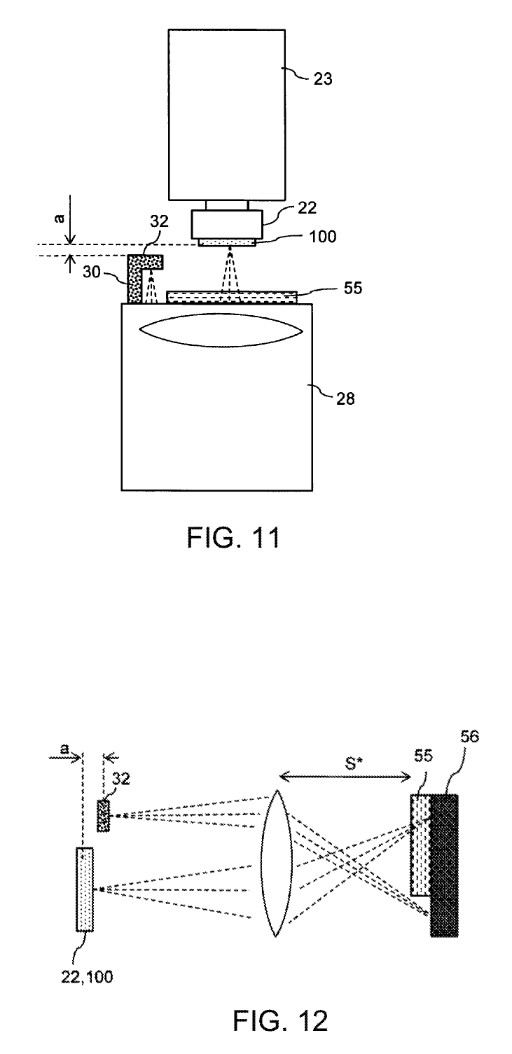

For example, as illustrated in FIG. 11, a portion of the cover glass 55 facing the reference mark 32 may be removed by providing a hole or a cutout for a part of a cover glass 55 of the bottom camera 28. Here, the working distance (focal position) becomes longer when extending beyond the cover glass 55, as compared to a case extending beyond the cover glass 55. Therefore, when the configuration as illustrated in FIG. 11 is employed, a major part of the view field of the bottom camera 28 where the cover glass 55 is provided may have a focal position more distant from the bottom camera 28 than the portion where the cover glass 55 is not provided (the portion facing the reference mark 32). Specifically, where a thickness of the cover glass 55 is d and a refractive index of the cover glass 55 is n, an extension amount a of the working distance (focal position) is a≈d (1−1/n). Accordingly, for example, if the thickness of the cover glass 55 d=1.5 mm and the refractive index of the cover glass 55 n=1.52, the working distance (focal position) increases by a≈0.5 mm. In other words, even when the reference mark 32 that is not influenced by the cover glass 55, and the collet 22 that is influenced by the cover glass 55 are disposed at the working distance (focal position), these two are positioned away from each other by the distance a. As a result, it is possible to focus on both of the reference mark 32 and the collet 22 while preventing interference between these two components.

Further, as a different configuration, as illustrated in FIG. 12, the cover glass 55 is provided so as to entirely cover a front side of a charge coupling device 56. This substantially means that a distance S* from a main surface on a back side of the lens to the charge coupling device (image surface) is reduced by b≈d (1−1/n). In this case, an amount of change a of a position of an object surface when a ratio is β is a≈b/β². Therefore, for example, a≈0.69 is established when the ratio R=0.7, the thickness of the cover glass d=1 mm, and the refractive index n=1.52. Thus, also in this case, even when the reference mark 32 that is not influenced by the cover glass 55, and the collet 22 that is influenced by the cover glass 55 are disposed at the working distance (focal position), these two are positioned away from each other by the distance a, and therefore it is possible to prevent interference between these two components.

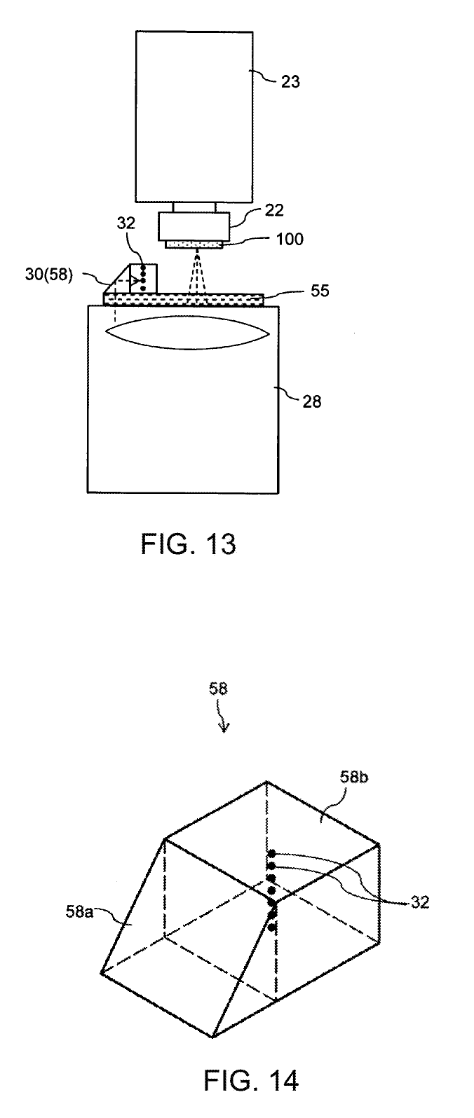

Moreover, instead of changing the working distance (focal position), an optical element for inflecting an optical path to the reference mark 32 may be provided as the reference member 30. FIG. 13 is a configurational diagram of the bottom camera 28 in this case, and FIG. 14 is a perspective view of an optical element 58 provided for the bottom camera 28. The optical element 58 in this example includes a prism or mirror 58a having a reflecting surface of 45 degrees with respect to the optical axis of the bottom camera 28, and a glass block 58b having the reference mark 32 therein. Within the glass block 58b, a plurality of point marks that function as the reference mark 32 are arranged at regular intervals in a vertical direction. The point marks may be provided within the glass block 58b using an ultrashort pulsed-laser such as a femtosecond laser. The optical element 58 thus configured is disposed on the end of the view field of the bottom camera 28, the optical path from the charge coupling device to the reference mark 32 is inflected. With this, the reference member 30 may be provided at a position displaced from the original working distance (focal position), and it is possible to prevent interference between the collet 22 and the reference member 30. Further, as illustrated in FIG. 14, by arranging the point marks as the reference mark 32 in a vertical direction, it is possible to focus on any of the point marks even when the focus position of the top camera 24 changes.

Moreover, in order to prevent interference, the reference member 30 may be configured as a movable type. In this case, the reference member 30 is first retracted to a retracted position, and the collet 22 is moved down to the working distance (focal position) of the bottom camera 28 to take an image in this state. Then the reference member 30 is moved to the reference position before the retraction to take an image in a state in which the collet 22 is moved upward. Subsequently, the obtained two images are combined, and thus the position of the collet 22 with respect to the reference mark 32 of the reference member 30 may be specified.

In any case, according to this embodiment, it is possible to obtain a change in the offset amount between the collet 22 and the top camera 24 without additionally providing a novel camera, and without additionally providing a complicated and time-consuming step.

### REFERENCE SIGNS LIST

10: Bonding apparatus
12: Chip feeding unit
14: Intermediate stage
16: Bonding stage unit
17: Movement mechanism
18: Bonding head
20: Stage
22: Collet
23: Z-axis drive mechanism
24: Top camera
26: XY table
28: Bottom camera
30: Reference member
32: Reference mark
40: Control unit
52: First image
54: Second image
55: Cover glass
56: Charge coupling device
58: Optical element
60: Plunge-up unit
100: Semiconductor chip
102: Wafer
104: Substrate

1. A bonding apparatus for bonding a chip onto a substrate, the apparatus comprising:
a bonding head configured to move a first camera facing toward a bonding surface and a bonding tool disposed with an offset from the first camera, while integrally holding the first camera and the bonding tool;
a second camera facing toward the bonding tool so as to detect a position of the chip held by the bonding tool with respect to the bonding tool;
a reference mark disposed within a view field of the second camera; and
a control unit configured to control movement of the bonding head, wherein
the control unit moves the bonding head based on a position of the reference mark recognized by the first camera, and then calculates a value of the offset based on a position of the bonding tool with respect to the reference mark recognized by the second camera.

2. The bonding apparatus according to claim 1, wherein
bonding is performed by feeding back the value of the offset calculated by the control unit to a subsequent bonding process.

3. The bonding apparatus according to claim 1, wherein
one of the first camera and the second camera takes an image of an imaging target without stopping the bonding head by causing electronic flash corresponding to the camera to emit light at imaging timing at which the imaging target passes through a view field of the camera as the bonding head moves, and
the control unit calculates the value of the offset based on the taken image obtained without stopping the bonding head.

4. The bonding apparatus according to claim 1, wherein
the control unit detects the position of the chip with respect to the bonding tool based on an image taken by the second camera for detecting the position of the bonding tool with respect to the reference mark.

5. The bonding apparatus according to claim 4, wherein
the second camera is an infrared camera for taking an image by infrared light.

6. The bonding apparatus according to claim 1, wherein
the reference mark is disposed on an end of a depth of field of the second camera.

7. The bonding apparatus according to claim 1, wherein
the second camera includes a mechanism for partially changing a focal position within the view field.

8. A bonding method of bonding a chip onto a substrate, the method comprising:
preparing a bonding apparatus including:
a bonding head configured to move a first camera facing toward a bonding surface and a bonding tool disposed with an offset from the first camera, while integrally holding the first camera and the bonding tool; and
a second camera facing toward the bonding tool so as to detect a position of the chip held by the bonding tool with respect to the bonding tool,
recognizing a position of a reference mark using the first camera, the reference mark being disposed within a view field of the second camera;
recognizing a position of the bonding tool with respect to the reference mark using the second camera after the bonding head is moved based on the position of the recognized reference mark; and
calculating a value of the offset based on the position of the bonding tool with respect to the recognized reference mark.
